(19) United States
(12) Patent Application Publication
(10) Pub. No.: US 2008/0258769 A1
(43) Pub. Date: Oct. 23, 2008

(54) Tri-State Circuit Element Plus Tri-State-Multiplexer Circuitry

(75) Inventors: Dirk Franger, Munchen (DE); Rolf Sautter, Hondorf (DE); Tobias Werner, Weil im Schoenbuch (DE); Pascal Witte, Freihurg (DE)

Correspondence Address: INTERNATIONAL BUSINESS MACHINES CORPORATION, IPLAW DEPARTMENT, 2455 SOUTH ROAD - MS P386, POUGHKEEPSIE, NY, 12601, US

(73) Assignee: INTERNATIONAL BUSINESS MACHINES CORPORATION, Armonk, NY (US)

(21) Appl. No.: 12/060,537

(22) Filed: Apr. 1, 2008

(30) Foreign Application Priority Data
Apr. 18, 2007 (EP) 07106401.8

(51) Int. Cl. H03K 19/00

(52) U.S. Cl. 326/58

(57) ABSTRACT

A Tri-State circuit element (100) composed of Complementary Metal Oxide Semiconductor (CMOS)—devices is described. Said Tri-State circuit element (100) having a data signal input terminal (102) for receiving a data signal, an enable signal input terminal (104) for receiving an enable signal, and an output signal terminal (106) for providing an output signal. Furthermore a Tri-State-Multiplexer circuitry (300) composed of such Tri-State circuit elements (100) is described.

### BACKGROUND OF THE INVENTION

The invention relates to a Tri-State circuit element plus a Tri-State-Multiplexer circuitry.

Tri-State-Multiplexer circuitries are well known from the state of the art. Within microprocessors they can be used e.g. to connect small on-chip memories, like e.g. a pre-stage of a cache with a, compared to the on-chip memory relatively large cache memory that can be arranged on- or off-chip. Thereby the Tri-State-Multiplexer circuitry is used to select one single data signal of a small number of data signals of the pre-stage to be forwarded to the cache.

Regarding this utilization of a Tri-State-Multiplexer circuitry, the relatively weak, i.e. small data signal from a selected Tri-State circuit element of the Tri-State-Multiplexer circuitry is available to be used to drive the cache. For maximum performance, the data signal has to be propagated to the cache as fast as possible. Since according to the state of the art the data signal of the on-chip memory's Tri-State-Multiplexer circuitry is too weak to drive the cache directly, amplification is necessary. In order to amplify the data signal, intermediate circuitries arranged between the on-chip memory Tri-State-Multiplexer circuitry and the cache are used. This approach is disadvantageous regarding performance, input capacitances and delay time. Further this approach requires a huge amount of devices, i.e. semi-conductor elements, particularly transistors, within the Tri-State-Multiplexer circuitry and the intermediate circuitries resulting in high power consumption, large area requirement and due to this high power leakage.

Tri-State-Multiplexer circuitries are composed of Tri-State circuit elements like e.g. a standard passgate structure 1 schematically shown in FIG. 1, a NAND gate structure 2 schematically shown in FIG. 2, an And-Or-Inverter Complex Gate (AOI) structure 3 schematically shown in FIG. 3.

An example for a Tri-State Complementary Metal Oxide Semiconductor (CMOS) circuit element 4 is shown in FIG. 4. By three such Tri-State CMOS circuit elements 4 a Tri-State-Multiplexer circuitry 5 is composed.

From U.S. Pat. No. 4,465,945 a Tri-State circuit element is known which is uniquely suited for use in large scale integrated circuit devices, wherein a relatively large number of such Tri-State circuit elements are utilized to drive other circuitry contained within the integrated circuit device. The Tri-State circuit element is either constructed utilizing a single NAND gate, a single inverter, a single P channel transistor and two N channel transistors, or utilizing a single NOR gate, a single inverter, a single N channel transistor and two P channel transistors. In both cases a Tri-State circuit element having a propagation delay of two gate delays per gate delay is yielded, consisting of a total of nine Metal Oxide Semiconductor (MOS) transistors.

This Tri-State circuit element due to its only nine devices has a low area requirement with only a small power leakage but it is too weak to be used to build an on-chip memory's Tri-State-Multiplexer circuitry to directly drive a cache. So using a Tri-State-Multiplexer circuitry composed of such Tri-State circuit elements for this purpose also needs an intermediate amplification by at least one intermediate circuitry.

### SUMMARY OF THE INVENTION

It is therefore an object of the invention to provide a high performance low power consumptive Tri-State circuit element for driving high output loads plus a Tri-State-Multiplexer circuitry composed of such elements.

An object of the invention is met by said Tri-State circuit element according to claim 1. Another object of the invention is met by said Tri-State-Multiplexer circuitry according to claim 3.

Said Tri-State circuit element according to the invention has the advantage over the state of the art, that it can be used to drive high output loads that are highly constrained on cycle time, i.e. driving high output loads with short gate delay. Regarding the ability to drive high output loads, the Tri-State-Multiplexer circuitry according to the invention has a reduced set of devices and an improved performance compared to a Tri-State-Multiplexer circuitry plus an intermediate circuitry needed for an intermediate amplification according to the state of the art. Further the Tri-State-Multiplexer circuitry according to the invention has very low input capacitances compared to the state of the art Tri-State-Multiplexer circuitries. The Tri-State-Multiplexer circuitry according to the invention further is area optimized due to its reduced set of devices resulting in a reduced power leakage.

### BRIEF DESCRIPTION OF THE DRAWINGS

The foregoing, together with other objects, features, and advantages of this invention can be better appreciated with reference to the following specification, claims and drawings, where

FIG. 1 schematically shows a standard passgate structure according to the state of the art,

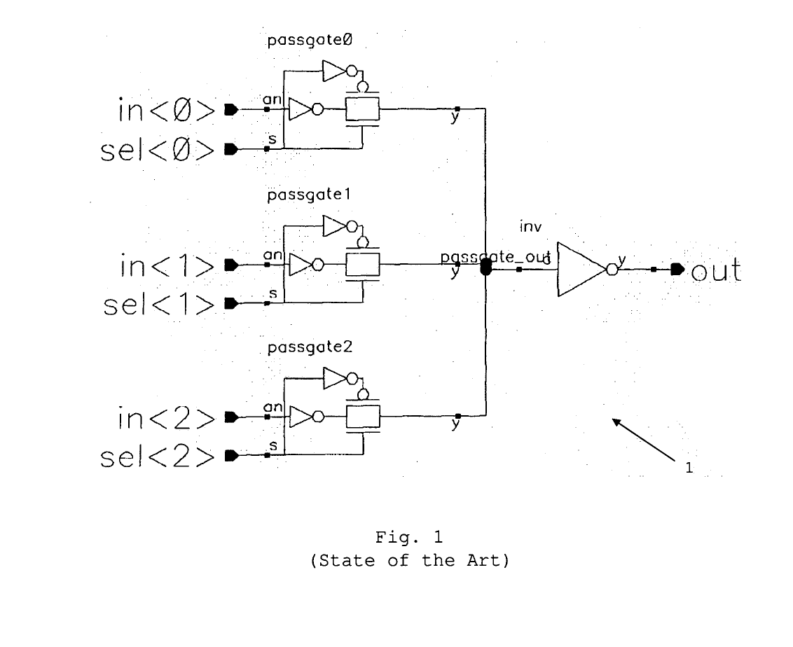

FIG. 2 schematically shows a NAND gate structure according to the state of the art,

FIG. 3 schematically shows an AOI structure according to the state of the art,

FIG. 4 schematically shows a Tri-State CMOS circuit element according to the state of the art,

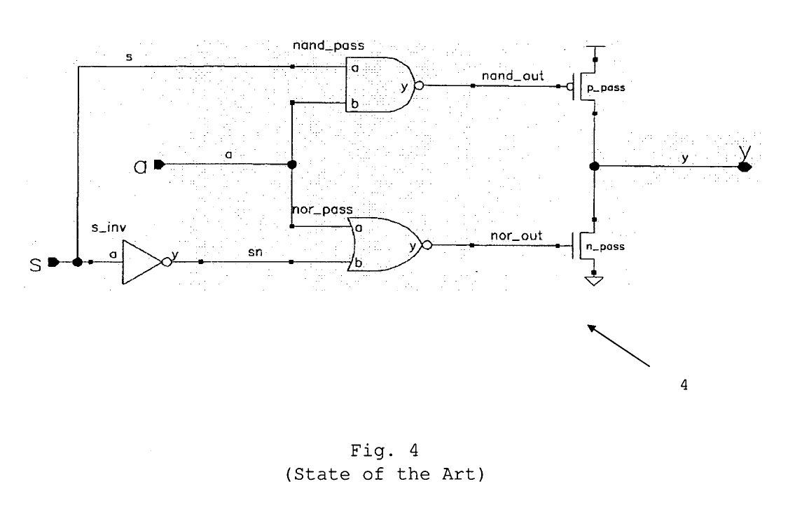

FIG. 5 schematically shows a Tri-State-Multiplexer circuitry according to the state of the art,

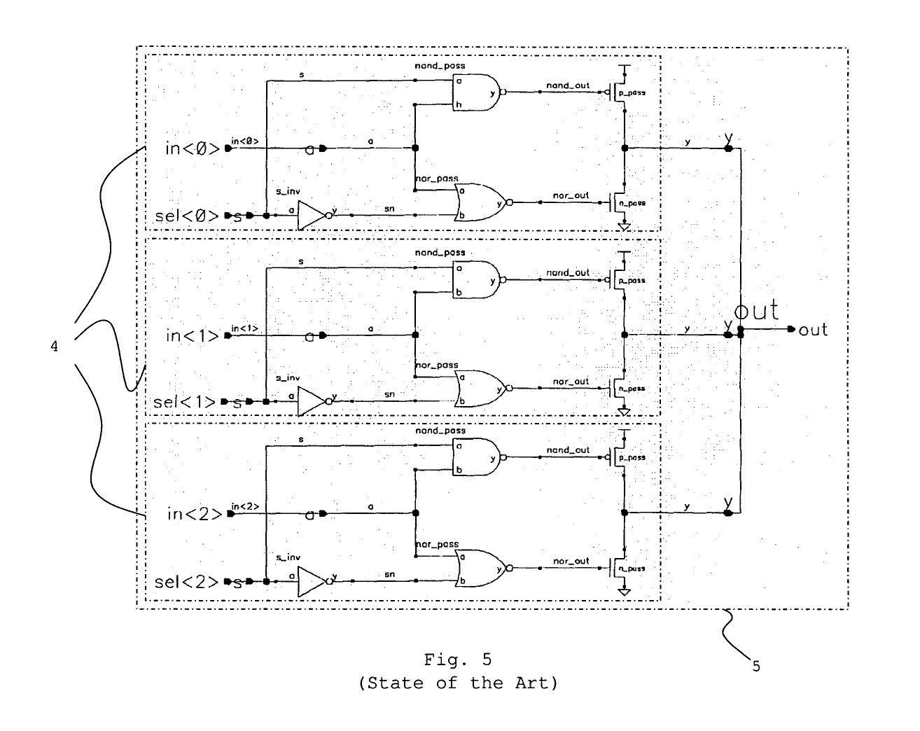

FIG. 6 schematically shows a Tri-State CMOS circuit element according to the invention, and

FIG. 7 schematically shows a Tri-State-Multiplexer circuitry according to the invention.

### DETAILED DESCRIPTION

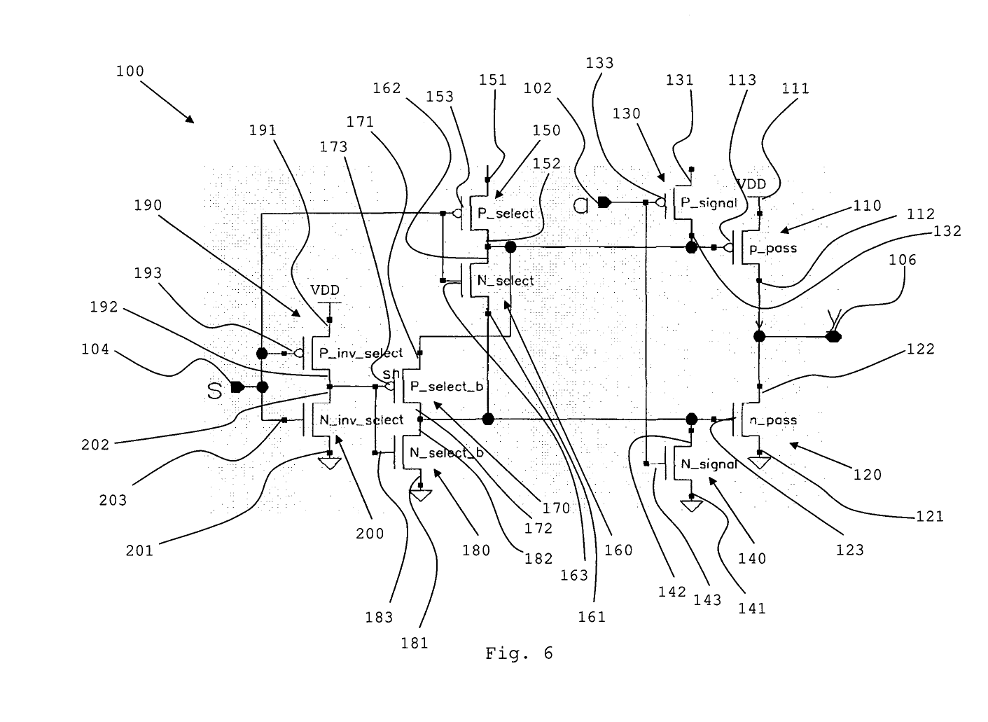

A Tri-State circuit element 100 according to the invention is shown in FIG. 6. The Tri-State circuit element 100 is composed of Complementary Metal Oxide Semiconductor (CMOS)—devices, i.e. transistors. The Tri-State circuit element 100 has a data signal input terminal 102 for receiving a data signal, an enable signal input terminal 104 for receiving an enable signal, and an output signal terminal 106 for providing an output signal. The Tri-State circuit element 100 further has a first CMOS transistor 110 of a first conductivity type having a source 111, a drain 112, and a gate 113, said source 111 being connected to a supply voltage VDD, and said drain 112 being connected to said output signal terminal 106. The Tri-State circuit element 100 also has a second CMOS transistor of a second conductivity type opposite to said first conductivity type, said second CMOS transistor having a drain connected to said output signal terminal 106, a source 121 connected to ground and a gate 123. Additionally the Tri-State circuit element 100 has a third CMOS transistor 130 of said first conductivity type, having a source 131 connected to said supply voltage VDD, a gate 133 connected to said data signal input terminal 102, and a drain 132 connected to the gate 113 of said first CMOS transistor 110, and a fourth CMOS transistor 140 of said second conductivity type with a source connected to ground, a gate 143 connected to said data signal input terminal 102, and a drain 142 connected to the gate 123 of said second CMOS transistor 120. The Tri-State circuit element 100 in addition has a fifth CMOS transistor of said first conductivity type with a source 151 connected to said supply voltage VDD, a drain 152 connected to the gate 113 of said first CMOS transistor 110, and a gate 153 connected to said enable signal input terminal 104, and a sixth CMOS transistor 160 of said second conductivity type with a source 161 connected to the gate 123 of said second CMOS transistor 120, a drain 162 connected to the gate 113 of said first CMOS transistor 110, and a gate 163 connected to said enable signal input terminal 104. Furthermore the Tri-State circuit element 100 has a seventh CMOS transistor 170 of said first conductivity type with a source 171 connected to the gate 113 of said first CMOS transistor 110, a drain 172 connected to the gate 123 of said second CMOS transistor 120, and a gate 173, plus an eighth CMOS transistor 180 of said second conductivity type with a source 181 connected to ground, a drain 182 connected to the gate 123 of said second CMOS transistor 120, and a gate 183. Finally the Tri-State circuit element 100 comprises a ninth CMOS transistor 190 of said first conductivity type with a source 191 connected to said supply voltage VDD, a drain 192 connected to said gate 173 of said seventh CMOS transistor 170 and to said gate 183 of said eighth CMOS transistor 180, and a gate 193 connected to said enable signal input terminal 104, and a tenth CMOS transistor 200 of said second conductivity type with a source 201 connected to ground, a drain 202 connected to said gate 173 of said seventh CMOS transistor 170 and to said gate 183 of said eight CMOS transistor 180, and a gate 203 connected to said enable signal input terminal 104. Said first conductivity type is a P-doped conductivity type, and said second conductivity type is a N-doped conductivity type.

The invention provides a Tri-State circuit element 100 with a very good relation of driver intensity at the output signal terminal 106 and capacitance at the input terminals 102, 104, particularly at the data signal input terminal 102. Those qualities of the Tri-State circuit element 100 according to the invention provide very fast circuit switching with high robustness compared e.g. with dynamic CMOS-circuitries according to the state of the art. So the Tri-State circuit element 100 provides a powerful data signal that is able to drive a cache directly having a propagation delay of about only one gate delay.

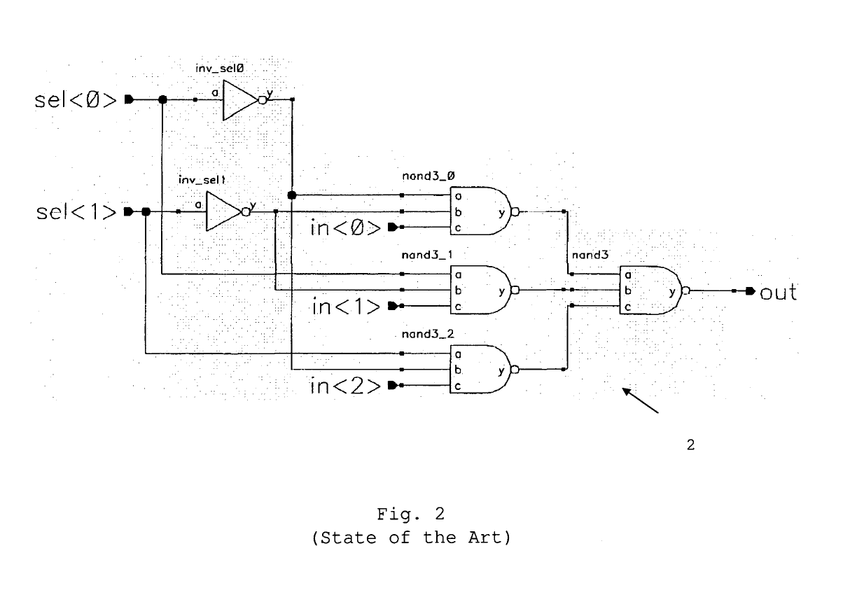

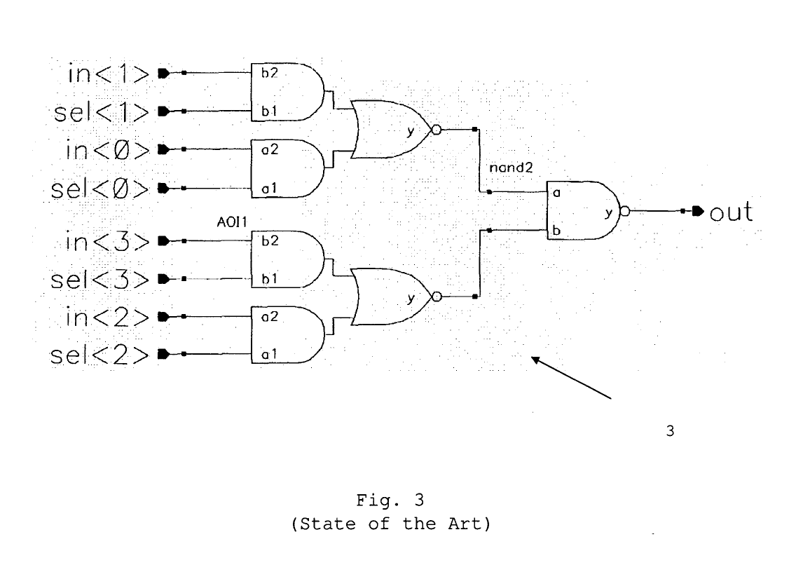

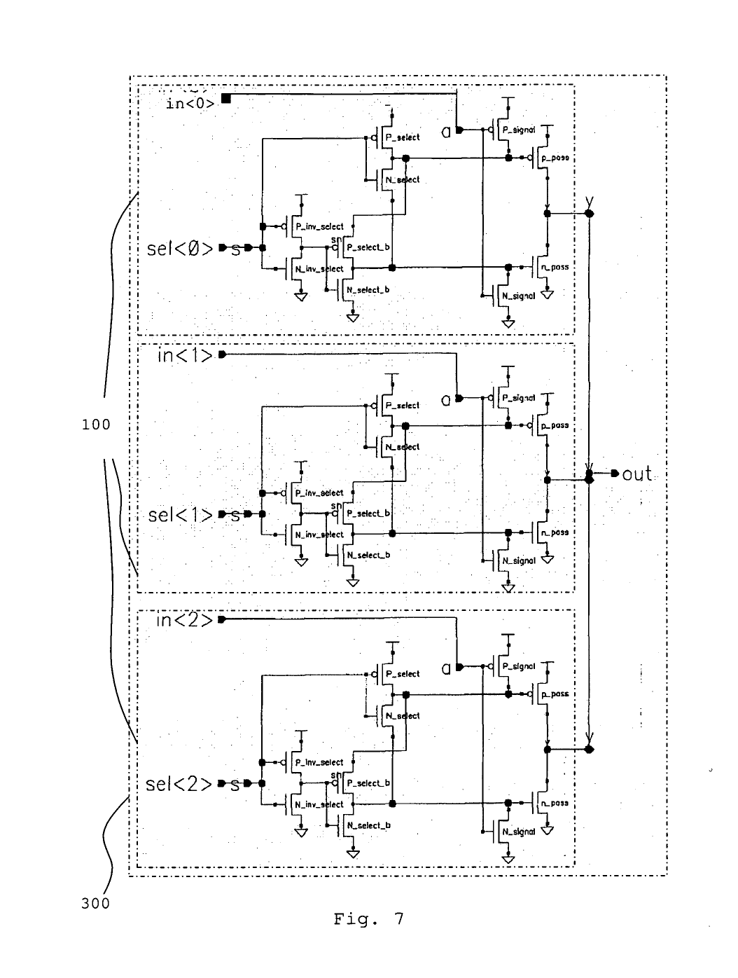

A Tri-State-Multiplexer circuitry 300 shown in FIG. 7 is composed of three such Tri-State circuit elements 100. In general, three or more Tri-State circuit elements 100 according to the invention can be combined to a Tri-State-Multiplexer circuit. It is an important advantage of the invention that many Tri-State circuit elements 100 can be combined to a large Multiplexer by simply interconnecting the output signal terminals 106 of those Tri-State circuit elements 100. This keeps Tri-State-Multiplexer circuitries according to the invention small compared to the state of the art, where structures 2 or 3 as shown in FIG. 2 or 3 to be combined to a multiplexer result in very large circuitries if more than four input signals are to be multiplexed. The Tri-State circuit element 100 shown in FIG. 6 allows achieving all the advantages of the invention.

For a better understanding of the invention, in the following the functionality of a Tri-State circuit element 100 is described with reference to FIGS. 6 and 7. Thereby the net interconnecting the connections 113, 132, 152, 171 and 162 is called Net A, and the net interconnecting the connections 172, 182, 161, 142 and 123 is called Net B (FIG. 6). An idea behind the Tri-State circuit element 100 according to the invention is to short-circuit Net A and Net B via the enable signal input terminal 104. The CMOS transistors 160 and 170 act as passgate. To achieve the same functionality, one of the two CMOS transistors 160, 170 but not both can be omitted. Electrically it is advantageous to have both CMOS transistors 160, 170 within the Tri-State circuit element 100.

If a Tri-State circuit element 100 within a Tri-State-Multiplexer circuitry 300 shown in FIG. 7 by an enable signal sel<0>, sel<1> or sel<2> via the enable signal input terminal 104 is selected, Net A and Net B are short-circuited and due to this have the same electric potential, i.e. voltage. In this case, the selected Tri-State circuit element 100 acts like a normal buffer. This allows the direct and high amplification of the data signal in <0>, in <1> or in <2> (depending on which Tri-State circuit element 100 within the Tri-State-Multiplexer circuit 300 is selected) from the data signal input terminal 102 to the output signal terminal 106.

If the Tri-State circuit element 100 is deselected, the short-circuit is cancelled. In this case a logic ‘1’ is applied on Net A by connecting Net A via the CMOS transistor 150 to the supply voltage VDD. Further a logic ‘0’ is applied on Net B by connecting Net B via the CMOS transistor 180 to ground. By connecting Net A to the supply voltage VDD and by connecting Net B to ground the CMOS transistors 110 and 120 are switched off and the output signal terminal 106 has a high resistance. Thereby a data signal in <0>, in <1> or in <2> (depending on which Tri-State circuit element 100 within the Tri-State-Multiplexer circuit 300 is selected) applied on the data signal input terminal 102 has no logical influence on the value, i.e. electric potential or voltage at the output signal terminal 106.

While the present invention has been described in detail, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

1. Tri-State circuit element (100) composed of Complementary Metal Oxide Semiconductor (CMOS)—devices, said Tri-State circuit element (100) having a data signal input terminal (102) for receiving a data signal, an enable signal input terminal (104) for receiving an enable signal, and an output signal terminal (106) for providing an output signal, characterized by
a first CMOS transistor (110) of a first conductivity type having a source (111), a drain (112), and a gate (113), said source (111) being connected to a supply voltage (VDD), and said drain (112) being connected to said output signal terminal (106),
a second CMOS transistor (120) of a second conductivity type opposite to said first conductivity type, said second CMOS transistor having a drain (122) connected to said output signal terminal (106), a source (121) connected to ground and a gate (123),
a third CMOS transistor (130) of said first conductivity type, having a source (131) connected to said supply voltage (VDD), a gate (133) connected to said data signal input terminal (102), and a drain (132) connected to the gate (113) of said first CMOS transistor (110),
a fourth CMOS transistor (140) of said second conductivity type with a source (141) connected to ground, a gate (143) connected to said data signal input terminal (102), and a drain (142) connected to the gate (123) of said second CMOS transistor (120),
a fifth CMOS transistor (150) of said first conductivity type with a source (151) connected to said supply voltage VDD, a drain (152) connected to the gate (113) of said first CMOS transistor (110), and a gate (153) connected to said enable signal input terminal (104),
a sixth CMOS transistor (160) of said second conductivity type with a source (161) connected to the gate (123) of said second CMOS transistor (120), a drain (162) connected to the gate (113) of said first CMOS transistor (110), and a gate (163) connected to said enable signal input terminal (104),
a seventh CMOS transistor (170) of said first conductivity type with a source (171) connected to the gate (113) of said first CMOS transistor (110), a drain (172) connected to the gate (123) of said second CMOS transistor (120), and a gate (173),
an eighth CMOS transistor (180) of said second conductivity type with a source (181) connected to ground, a drain (182) connected to the gate (123) of said second CMOS transistor (120), and a gate (183),
a ninth CMOS transistor (190) of said first conductivity type with a source (191) connected to said supply voltage VDD, a drain (192) connected to said gate (173) of said seventh CMOS transistor (170) and to said gate (183) of said eight CMOS transistor (180), and a gate (193) connected to said enable signal input terminal (104),
a tenth CMOS transistor (200) of said second conductivity type with a source (201) connected to ground, a drain (202) connected to said gate (173) of said seventh CMOS transistor (170) and to said gate (183) of said eight CMOS transistor (180), and a gate (203) connected to said enable signal input terminal (104).

2. Tri-State circuit element according to claim 1, characterized in that said first conductivity type is a P-doped conductivity type, and said second conductivity type is a N-doped conductivity type.

3. Tri-State circuit element according to claim 1, characterized in that either the sixth or the seventh CMOS transistor (160 or 170) is omitted.

4. Tri-State-Multiplexer circuitry (300) composed of at least three Tri-State circuit elements (100) according to one of the claim 1.
